(19) United States
(12) Patent Application Publication
(10) Pub. No.: US 2014/0138138 A1
(43) Pub. Date: May 22, 2014

(54) PRINTED CIRCUIT BOARD HAVING ELECTRONIC COMPONENT EMBEDDED THEREIN

(71) Applicant: SAMSUNG ELECTRO-MECHANICS CO., LTD., Suwon (KR)

(72) Inventors: Sung Yeol Park, Suwon (KR); Suk Jin Ham, Suwon (KR); Seung Heon Han, Suwon (KR)

(73) Assignee: SAMSUNG ELECTRO-MECHANICS CO., LTD., Suwon (KR)

(21) Appl. No.: 13/830,786

(22) Filed: Mar. 14, 2013

(30) Foreign Application Priority Data
Nov. 19, 2012 (JP) 10-2012-0130828

(51) Int. Cl. H05K 1/18

(52) U.S. Cl. CPC H05K 1/183
USPC 174/260

(57) ABSTRACT

Disclosed herein is a printed circuit board having an electronic component embedded therein, the printed circuit board including: the electronic component having an external electrode formed on one side surface or both side surfaces thereof; a base substrate having a cavity into which the electronic component is inserted; and at least one connection member inserted between the external electrode of the electronic component and an inner wall of the cavity to electrically connect the electronic component and the base substrate to each other.

### CROSS REFERENCE TO RELATED APPLICATION

This application claims the benefit of Korean Patent Application No. 10-2012-0130828, filed on Nov. 19, 2012, entitled “Printed Circuit Board embedding Electronic Component”, which is hereby incorporated by reference in its entirety into this application.

### BACKGROUND OF THE INVENTION

1. Technical Field

The present invention relates to a printed circuit board having an electronic component embedded therein.

2. Description of the Related Art

Generally, in a printed circuit board on which electronic components including a passive device, an active device, and the like, are mounted, after internal circuits are formed, pads that are connected to the internal circuit and are to mount the electronic components are formed on a surface of the printed circuit board.

When the electronic components are mounted on the pads and then subjected to a reflow process, the mounting of the electronic components is completed.

However, as performance of a product is improved, the number of electronic components mounted on the printed circuit board has increased, the number of circuit patterns formed on the printed circuit board has increased, and the circuit patterns have been complicated. Therefore, an area in which the electronic components may be mounted has decreased.

In addition, the demand for slimness and lightness of the product has increased.

As one of the methods for solving the above-mentioned problem and satisfying the above-mentioned demand, a structure in which the electronic component mounted on the printed circuit board is embedded in the printed circuit board has been developed.

In this case, an electrode of the electronic component and a circuit pattern of the printed circuit board should be electrically connected to each other. According to the prior art, a via hole for exposing an electrode portion of the electronic component embedded in the printed circuit board was formed, and an inner portion of the via hole was plated to foil 1 a via, thereby electrically connecting the via and the circuit pattern of the printed circuit to board to each other.

Meanwhile, a structure of the printed circuit board into which the electronic component according to the prior art described above is embedded has been disclosed in U.S. Pat. No. 8,237,060.

### SUMMARY OF THE INVENTION

The present invention has been made in an effort to provide a printed circuit board having an electronic component embedded therein, having a structure capable of fixing the electronic component inserted into a cavity and electrically connecting the electronic component to the printed circuit board.

According to a preferred embodiment of the present invention, there is provided a printed circuit board having an electronic component embedded therein, the printed circuit board including: the electronic component having an external electrode formed on one side surface or both side surfaces thereof; a base substrate having a cavity into which the electronic component is inserted; and at least one connection member inserted between the external electrode of the electronic component and an inner wall of the cavity to electrically connect the electronic component and the base substrate to each other.

The connection member may fix the electronic component inserted into the cavity.

The connection member may be made of a conductive material.

The electronic component may have a chamfering part formed at at least one of edges of one side surface or both side surfaces thereof in a thickness direction, and the connection member may be inserted between the chamfering part and the inner wall of the cavity.

The electronic component may have at least one groove part formed in one side surface or both side surfaces thereof in a thickness direction, and the connection member may be inserted between the groove part and the inner wall of the cavity.

The groove part may have a circular, triangular, rectangular, or polygonal cross to section.

The electronic component may include: a body including a plurality of internal electrodes multilayered at predetermined intervals; and external electrodes formed on both side surfaces of the body in the thickness direction, wherein the plurality of internal electrodes are alternately exposed to one side surface and the other side surface of the body to thereby be electrically connected to the external electrodes.

The base substrate may include: a via electrically connected to the connection member; and a circuit pattern electrically connected to the via, and the electronic component may be electrically connected to the circuit pattern through the external electrode, the connection member, and the via.

The electronic component may be a multilayer ceramic capacitor (MLCC).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view showing a structure of an electronic component according to a preferred embodiment of the present invention;

FIGS. 2A and 2B are, respectively, plan views showing a first internal electrode and a second internal electrode of the electronic component of FIG. 1;

FIG. 3 is a plan view showing a structure in which the first and second internal electrodes of FIG. 2 are multilayered; FIG. 4 is a perspective view showing a structure of an electronic component according to another preferred embodiment of the present invention;

FIG. 5 is a plan view showing a structure in which first and second internal electrodes of the electronic component of FIG. 4 are multilayered;

FIG. 6 is a plan view showing a structure of a printed circuit board having an to electronic component according to a preferred embodiment of the present invention embedded therein;

FIG. 7 is a cross-sectional view taken along the line A-A′ of FIG. 6; and

FIG. 8 is a plan view showing a structure of a printed circuit board having an electronic component of FIG. 4 embedded therein.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the teens “first”, “second”, “one side”, “the other side” and the like are used to differentiate a certain component from other components, but the configuration of such components should not be construed to be limited by the teens. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

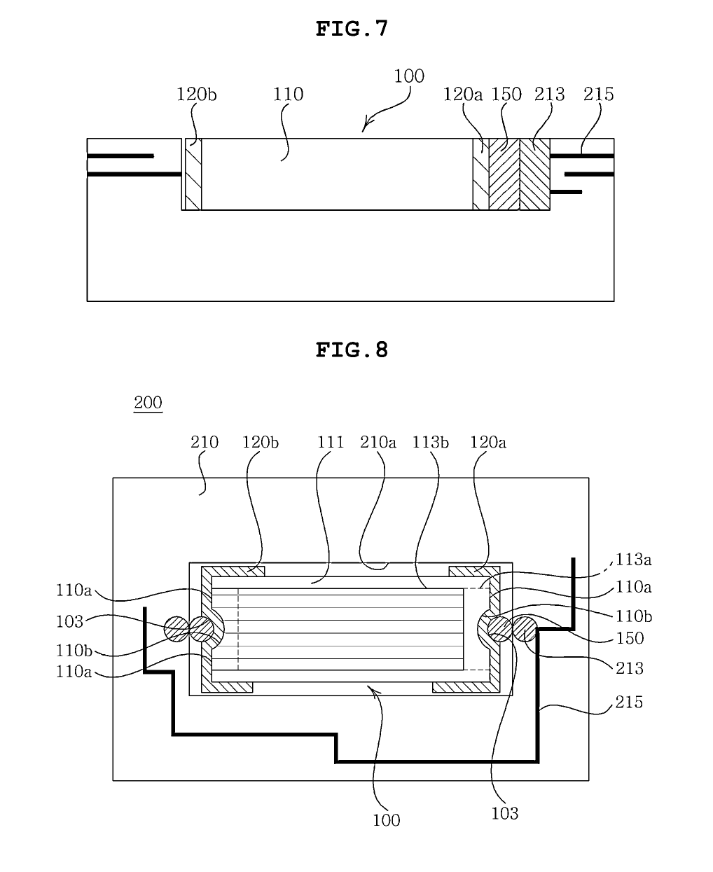

FIG. 6 is a plan view showing a structure of a printed circuit board having an electronic component according to a preferred embodiment of the present invention embedded therein; FIG. 7 is a cross-sectional view taken along the line A-A′ of FIG. 6; and FIG. 8 is a plan view showing a structure of a printed circuit board having an electronic component of FIG. 4 embedded therein.

Referring to FIGS. 6 and 7, the printed circuit board 200 having an electronic component embedded therein according to the present embodiment is configured to include the electronic component 100 having an external electrode 120 formed on one side surface to or both side surfaces thereof, a base substrate 210 having a cavity 210a into which the electronic component 100 is inserted, and at least one connection member 150 inserted between the external electrode 120 of the electronic component 100 and an inner wall of the cavity 210a to electrically connect the electronic component 100 and the base substrate 210 to each other.

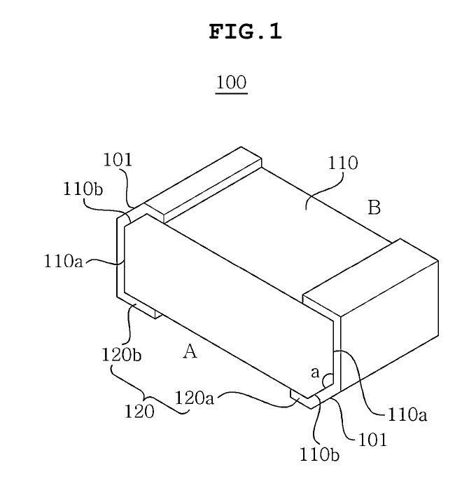

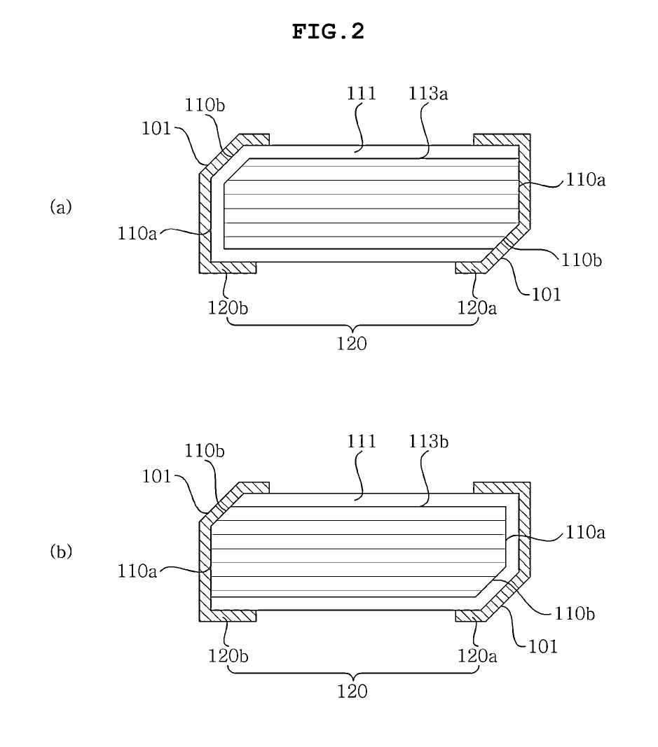

In the present embodiment, the electronic component 100 may have a chamfering part 101 formed at at least one of edges of both side surfaces thereof in a thickness direction, as shown in FIG. 1. Although the case in which two chamfering parts 101 are formed at two edges positioned in a diagonal direction in edges of both sides of the electronic component 100 is shown in FIG. 1, this is only an example. That is, positions and the number of chamfering parts 101 are not limited thereto.

Here, the “thickness direction” means a direction from an upper surface A (See FIG. 1) of the electronic component 100 inserted into the cavity 210a toward a lower surface B (See FIG. 1) thereof, wherein the ‘upper surface’ of the electronic component 100 means a surface exposed upwardly when the electronic component 100 is inserted into the cavity 210a of the printed circuit board, and the ‘lower surface’ of the electronic component 100 means a surface contacting a bottom surface of the cavity 210a.

The above-mentioned meaning may be similarly applied to the ‘thickness direction’ described below.

Meanwhile, the electronic component 100 according to another preferred embodiment of the present invention may include at least one groove part 103 formed in both side surfaces thereof in the thickness direction, as shown in FIG. 4.

Although the case in which two groove parts 103 are formed at positions of both side surfaces corresponding to each other is shown in FIG. 4, this is only an example. That is, positions and the number of groove parts 103 are not limited thereto.

In addition, although the case in which the groove part 103 has a circular cross section is shown in FIG. 4, this is only an example. That is, in the present embodiment, the to groove part 103 may have a triangular, rectangular, or a polygonal cross section.

More specifically, the electronic component 100 according to the present embodiment may include a body 110 having a first surface 110a and a second surface 110b connected to the first surface 110a and having a height different from that of the first surface 110a and external electrodes 120 each formed on both side surfaces of the body and having the same thickness at a portion corresponding to the first surface 110a and a portion corresponding to the second surface 110b.

Although a multilayer ceramic capacitor (MLCC) will be described as an example of the electronic component 100 in the present embodiment, a structure according to the present embodiment is not particularly limited to being applied to the multilayer ceramic capacitor (MLCC), but may also be applied to any kind of electronic component.

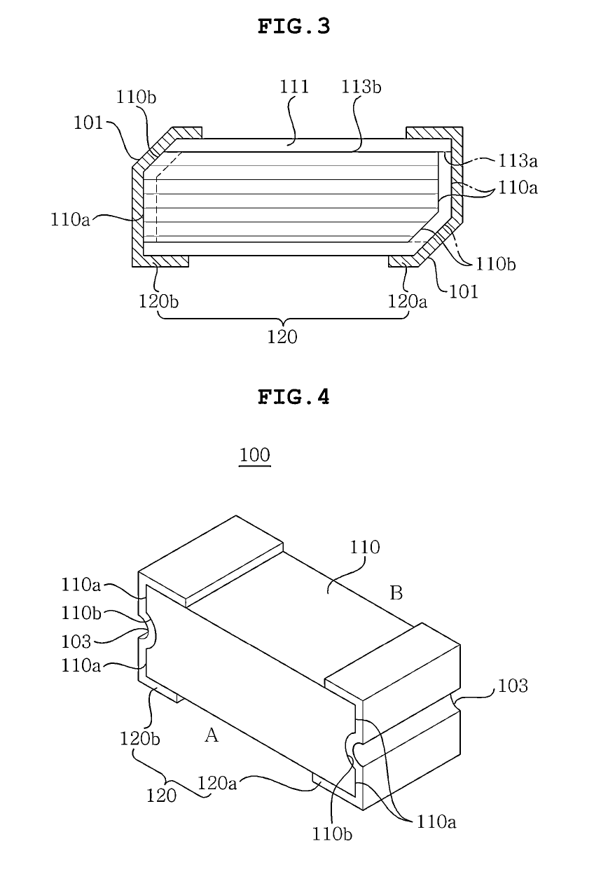

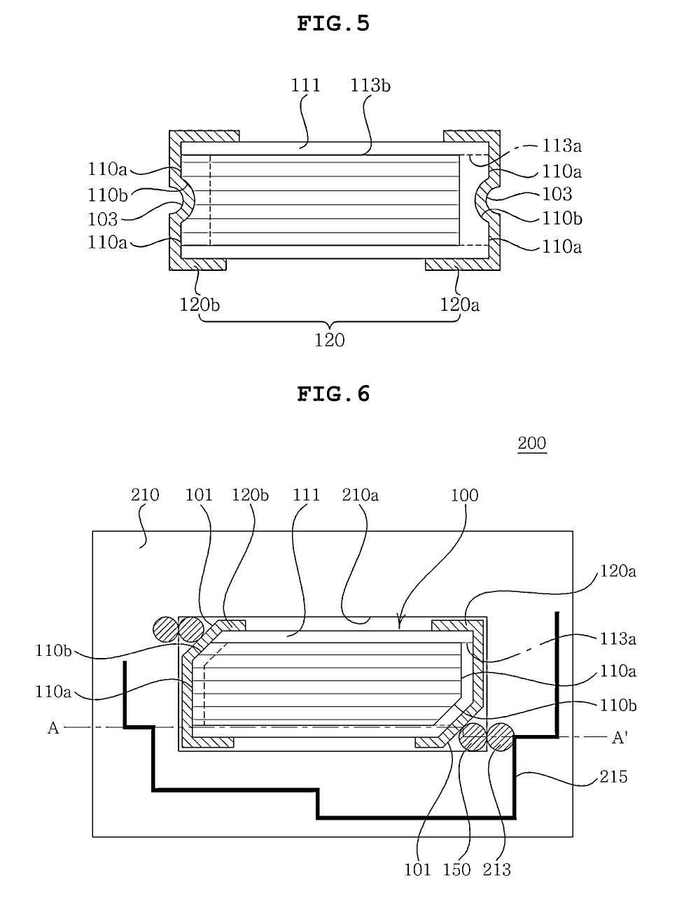

Therefore, the body 110 of the electronic component 100 according to the present embodiment may include a first internal electrode 113a formed on one ceramic layer 111 and a second internal electrode 113b formed on another ceramic layer 111 positioned on or beneath one ceramic layer 111 and formed at a position symmetrical to the first internal electrode 113a in the diagonal direction, wherein the ceramic layer 111 having the first internal electrode 113a formed thereon and the ceramic layer 111 having the second internal electrode 113b formed therein may be multilayered as shown in FIG. 3.

In addition, a plurality of ceramic layers 111 each having the first internal electrode 113a formed thereon and a plurality of ceramic layers 111 each having the second internal electrode 113b formed therein are alternately multilayered, thereby making it possible to form the body 110 having a multilayer structure. Here, the first internal electrode 113a may be exposed to one side surface of both side surfaces of the body 110 in the thickness direction, and the second internal electrode may be exposed to the other side surface thereof as opposed to the first internal electrode 113a.

That is, the first and second internal electrodes 113a and 113b are exposed to surfaces facing each other, respectively. This is similarly applied to the plurality of first internal electrodes 113a and the plurality of second internal electrodes 113b that are alternately multilayered.

In addition, in the present embodiment, the external electrode 120 may include a first external electrode 120a formed on one side surface of both side surfaces of the body 110 in the thickness direction and a second external electrode 120b formed on the other side surface thereof, wherein the first external electrode 120a formed on one side surface of the body 100 may contact the first internal electrode 113a exposed to one side surface of the body 110 and the second external electrode 120b formed on the other side surface thereof may contact the second internal electrode 113b exposed to the other side surface of the body 110.

Therefore, each of the first and second internal electrodes 113a and 113b formed in the body 110 of the electronic component 100 may be electrically connected to circuit patterns formed on a printed circuit board in which the electronic component 100 will be subsequently embedded, through the first and second external electrodes 120a and 120b formed on both side surfaces of the body 110.

In addition, the first and second external electrodes 120a and 120b may be a positive electrode and a negative electrode, respectively, but are not particularly limited thereto.

Both side surfaces of the electronic component 100 according to the present embodiment may be configured of the first surface 110a and the second surface 110b connected to the first surface 110a, as described above.

Here, the first and second surfaces 110a and 110b may have different heights. Here, the meaning that the first and second surfaces 110a and 110b have the ‘different heights’ is that the first and second surfaces 110a 110b are not formed as flat surfaces, that is, the first and second surfaces 110a 110b are not flat.

More specifically, the second surface 110b may be foil led in a chamfered shape as shown in FIG. 1 or be formed in a shape of a groove bent inwardly of the body 110 as to shown in FIG. 4.

In addition, as described above, the external electrode 120 covering the first and second surfaces 110a and 110b having the different heights may have the same thickness at the portion corresponding to the first surface 110a and the portion corresponding to the second surface 110b.

This is to deform a shape of the side surfaces of the finally manufactured electronic component 100. As described above, the side surfaces are configured of the first and second surfaces 110a and 110b having the different heights, thereby making it possible to form a space between the inner wall of the cavity and the first surface 110a or between the inner wall of the cavity and the second surface 110b when the electronic component 100 will be subsequently inserted into the printed circuit board.

That is, as shown in FIGS. 6 and 8, a space may be formed between the chamfering part 101 and the groove part 103 of the electronic component 100 inserted into the cavity 210a of the base substrate 210 and the inner wall of the cavity 210a.

The connection member 150 may be inserted into the space faulted as described above.

In the present embodiment, the connection member 150 may be made of a conductive material. In addition, the connection member 150 may have the same diameter as that of the space, but is not particularly limited thereto.

However, the connection member 150 having the diameter corresponding to that of the space is used to fix the electronic component 100 inserted into the cavity 210, thereby making it possible to prevent the electronic component 100 from being separated from the base substrate 210.

According to the prior art, in order to fix the electronic component inserted into the cavity, a process of filling a gap between the inner wall of the cavity and the electronic component with a filler or a plating process has been separately performed. However, in the present embodiment, since the electronic component 100 may be fixed by inserting the to connection member 150, the above-mentioned processes are not required. Therefore, according to the preferred embodiment of the present invention, a manufacturing process may be simplified as compared with the prior art.

In addition, the connection member 150 made of the conductive material is inserted into the space between the external electrode 120 and the inner wall of the cavity 210a, thereby making it possible to electrically connect the external electrode 120 and the base substrate 210 to each other.

More specifically, the base substrate 210 according to the present embodiment may further include a via 213 partially exposed to the inner wall of the cavity 210a to contact the connection member 150 and a circuit pattern 215 electrically connected to the via 213.

Therefore, the electronic component 100 inserted into the cavity 210a may be electrically connected to the circuit pattern 215 of the base substrate 210 through the external electrode 120, the connection member 213, and the via 213.

As described above, since the electronic component 100 may be electrically connected to the circuit pattern of the printed circuit board through both side surfaces thereof by inserting the connection member 150 between both side surfaces of the electronic component 100 and the inner wall of the cavity, the external electrodes 120 need not to be formed on the upper surface A (See FIG. 1) and the lower surface B (See FIG. 1) of the electronic component 100, such that the upper and lower surfaces of the electronic component 100 may be maintained to be flat.

As described above, the upper and lower surfaces of the electronic component 100 embedded in the printed circuit board 200 are formed to be flat, such that a surface of the printed circuit board may also be planarized. In addition, since there is no electrode exposed to the upper and lower surfaces, a thickness of the printed circuit board 200 may be decreased by a corresponding thickness.

This is only an example. That is, a shape of the side surface according to the present embodiment may also be applied to a structure of the electronic component 100 according to the prior art, that is, a structure in which the external electrode is formed up to portions of the upper and lower surfaces.

That is, in the printed circuit board 200 having an electronic component embedded therein according to the present embodiment, a shape of an outer side of the electronic component 100 is deformed to foul' the space between the inner wall of the cavity 210a and the electronic component 100, and the connection member made of the conductive material is inserted into the space, thereby making it possible to fix the electronic component 100 inserted into the cavity 210a and electrically connect the electronic component 100 to the circuit pattern 215 of the base substrate 210 through the side surface of the electronic component 100.

According to the preferred embodiment of the present invention, the shape of the outer side of the electronic component embedded in the printed circuit board is deformed to form the space between the outer side of the electronic component and the inner wall of the cavity into which the electronic component is inserted, and the connection member made of the conductive material is inserted into the space, thereby making it possible to fix the electronic component inserted into the cavity and electrically connect the printed circuit board and the electronic component to each other.

In addition, according to the preferred embodiment of the present invention, as described above, since the connection member is inserted into the space between the electronic component and the inner wall of the cavity to fix the electronic component, the process of filling a gap between the electronic component and the inner wall of the cavity with the fill or the plating process needs not to be separately performed, such that a process may be simplified and a process cost may be decreased.

In addition, according to the preferred embodiment of the present invention, as described above, since the connection member is inserted into the space between the electronic component and the inner wall of the cavity to electrically connect the side surface of the electronic component and the printed circuit board to each other, the electrode needs not to be formed on the upper or lower surface of the electronic component, such that the electronic component having flat upper and lower surfaces may be manufactured.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board having an electronic component embedded therein, the printed circuit board comprising:
the electronic component having an external electrode formed on one side surface or both side surfaces thereof;
a base substrate having a cavity into which the electronic component is inserted; and
at least one connection member inserted between the external electrode of the electronic component and an inner wall of the cavity to electrically connect the electronic component and the base substrate to each other.

2. The printed circuit board as set forth in claim 1, wherein the connection member fixes the electronic component inserted into the cavity.

3. The printed circuit board as set forth in claim 1, wherein the connection member is made of a conductive material.

4. The printed circuit board as set forth in claim 1, wherein the electronic component has a chamfering part formed at at least one of edges of one side surface or both side surfaces thereof in a thickness direction, and
the connection member is inserted between the chamfering part and the inner wall of the cavity.

5. The printed circuit board as set forth in claim 1, wherein the electronic component has at least one groove part formed in one side surface or both side surfaces thereof in a thickness direction, and
the connection member is inserted between the groove part and the inner wall of the cavity.

6. The printed circuit board as set forth in claim 5, wherein the groove part has a circular, triangular, rectangular, or polygonal cross section.

7. The printed circuit board as set forth in claim 1, wherein the electronic component includes:
a body including a plurality of internal electrodes multilayered at predetermined intervals; and
external electrodes formed on both side surfaces of the body,
the plurality of internal electrodes being alternately exposed to one side surface and the other side surface of the body to thereby be electrically connected to the external electrodes.

8. The printed circuit board as set forth in claim 1, wherein the base substrate includes:
a via electrically connected to the connection member; and
a circuit pattern electrically connected to the via, and
wherein the electronic component is electrically connected to the circuit pattern through the external electrode, the connection member, and the via.

9. The printed circuit board as set forth in claim 1, wherein the electronic component is a multilayer ceramic capacitor (MLCC).
